(19) United States
(12) Patent Application Publication
(10) Pub. No.: US 2025/0243393 A1
(43) Pub. Date: Jul. 31, 2025

(54) HEAT-CURABLE ADHESIVE COMPOSITION, LAYERED FILM, CONNECTED STRUCTURE, AND PRODUCTION METHOD THEREFOR

(71) Applicant: Resonac Corporation, Minato-ku, Tokyo (JP)

(72) Inventors: Yuka TSUNASHIMA, Minato-ku, Tokyo (JP); Masanori NATSUKAWA, Minato-ku, Tokyo (JP)

(21) Appl. No.: 18/856,061

(22) PCT Filed: Apr. 6, 2023
(86) PCT No.: PCT/JP2023/014292

§ 371 Date: Oct. 11, 2024

(30) Foreign Application Priority Data
Apr. 15, 2022 (JP) 2022-067897

(51) Int. Cl. C09J 163/00; C08K 3/013; C08K 5/17; C08K 9/06; C09J 5/06; C09J 133/04

(52) U.S. Cl. CPC C09J 163/00; C08K 3/013; C08K 5/17; C08K 9/06; C09J 5/06; C09J 133/04; C09J 2301/408; C09J 2301/416

(57) ABSTRACT

A heat-curable adhesive composition containing: a photocleavable compound that generates an amine compound through cleavage induced by irradiation; and a heat-curable resin that cures upon heating in a presence of the amine compound. A layered film including: a substrate film; and an adhesive layer provided on a surface of the substrate film; wherein the adhesive layer is composed of the heat-curable adhesive composition.

### TECHNICAL FIELD

The present disclosure relates to a heat-curable adhesive composition, a layered film, a connected structure, and a method for producing the same.

### BACKGROUND ART

Conventionally, a semiconductor device is produced through the following steps. First, the semiconductor wafer is diced into semiconductor chips by performing a dicing step in a state where the semiconductor wafer is attached to the tacky sheet for dicing. Thereafter, a pickup step, a die bonding step, a wire bonding step, a molding step, and the like are performed. Patent Document 1 discloses a tacky adhesive sheet (die-bond dicing sheet) having both a function of fixing a semiconductor wafer in a dicing step and a function of adhering a semiconductor chip to a substrate in a die bonding step. Patent Document 2 discloses a tacky adhesive sheet that acts as a dicing tape in a dicing step, has excellent connection reliability in a bonding step between a semiconductor element and a support member, and retains sufficient fluidity after thermal history of wire bonding.

### CITATION LIST

### Patent Literature

Patent Literature 1: Japanese Unexamined Patent Publication No. 2007-288170
Patent Literature 2: Japanese Unexamined Patent Publication No. 2009-209345

### SUMMARY OF INVENTION

### Technical Problem

By the way, in recent years, with the evolution of semiconductor modules for small devices typified by smartphones, the producing process of semiconductor modules has also changed significantly from the conventional one. For example, a process in which a dicing step and a die bonding step are not performed has been put into practical use. Accordingly, an adhesive composition used in a producing process of a semiconductor module is also required to have performance different from conventional performance. In addition to such circumstances, the present inventors have assumed that a material having relatively low heat resistance is used for a semiconductor module, and have proceeded development of an adhesive composition in which a curing reaction sufficiently proceeds under a low temperature condition of 85° C. or lower. As a result of improvement based on a conventional heat-curable adhesive composition excellent in low-temperature curability, the development target for low-temperature curability could be achieved, but the shear viscosity easily increased over time, the usable period after preparation was about 3 weeks, and there was a new problem of prolongation of the usable period.

One aspect of the present disclosure is to provide a heat-curable resin composition that sufficiently suppresses an increase in shear viscosity over time, can be used for a relatively long period of time after preparation, and is useful for achieving a thermal curing treatment under a low temperature condition of 85° C. or lower. One aspect of the present disclosure provides an adhesive film including an adhesive layer composed of the heat-curable adhesive composition, a connected structure, and a method for producing the same.

### Solution to Problem

One aspect of the present disclosure relates to a heat-curable adhesive composition. This composition contains a photocleavable compound that generates an amine compound through cleavage induced by irradiation; and a heat-curable resin that cures upon heating in the presence of the amine compound. Examples of the radiation include an ultraviolet ray, an electron beam, and an infrared ray.

The composition exhibits heat-curable properties upon irradiation with radiation.

Therefore, even if the composition is not used immediately after preparation and is stored for a period of time, the progression of the curing reaction during that period is sufficiently suppressed. For this reason, the increase in shear viscosity over time is sufficiently suppressed, allowing the composition to remain usable for a relatively long period (for example, over four weeks) after preparation. That is, a sufficiently long work life can be achieved. In addition, the composition is also useful for achieving a thermal curing treatment at a low temperature condition of 85° C. or lower. That is, when a heat-curable resin having excellent low-temperature curability is stored in a state of being mixed with a curing accelerator, a curing reaction tends to easily proceed. However, since the photocleavable compound exhibits a function by being irradiated with radiation during use, the curing reaction of the heat-curable resin is suppressed during storage. According to the composition, it is possible to achieve both a long work life and low-temperature curability at a sufficiently high level.

One aspect of the present disclosure relates to a layered film. This layered film includes a substrate film and an adhesive layer provided on a surface of the substrate film, and the adhesive layer is composed of the heat-curable adhesive composition.

One aspect of the present disclosure relates to a method for producing a connected structure. This production method includes (A) preparing a layered body including a first circuit member, a second circuit member, and an adhesive layer disposed between the first circuit member and the second circuit member; (B) heating the layered body at 65 to 85° C. for 30 to 240 minutes; and (C) wire bonding the first circuit member and the second circuit member, in this order, wherein the adhesive layer is composed of the heat-curable adhesive composition, and the method includes a step of irradiating the adhesive layer with radiation before the step (B).

The heat-curable resin composition may be used for the production of a connected structure after the heat-curable resin composition is irradiated with radiation to exhibit heat-curable properties. The composition after irradiation with radiation contains an amine compound generated by cleavage of a photocleavable compound, and a heat-curable resin cured upon heating in the presence of the amine compound. When a connected structure is produced using this composition, the step (A), the step (B), and the step (C) may be sequentially performed.

One aspect of the present disclosure relates to a connected structure. The connected structure includes a first circuit member, a second circuit member, and an adhesive layer disposed between the first circuit member and the second circuit member, and the adhesive layer is composed of a cured product of the heat-curable adhesive composition. In the present disclosure, for example, the first circuit member is one selected from the group consisting of a printed circuit board and a semiconductor chip, and the second circuit member is a flexible printed circuit board.

### Advantageous Effects of Invention

According to one aspect of the present disclosure, there is provided a heat-curable resin composition that sufficiently suppresses an increase in shear viscosity over time, can be used for a relatively long period of time after preparation, and is useful for achieving a thermal curing treatment under a low temperature condition of 85° C. or lower. According to one aspect of the present disclosure, there are provided an adhesive film including an adhesive layer composed of the heat-curable adhesive composition, a connected structure, and a method for producing the same.

### BRIEF DESCRIPTION OF DRAWINGS

FIG. 1 is a cross-sectional view schematically illustrating an embodiment of a layered film according to the present disclosure.

FIG. 2 is a cross-sectional view schematically illustrating a state of a producing process of a semiconductor module.

FIG. 3 is a cross-sectional view schematically illustrating a state of a producing process of a semiconductor module.

FIG. 4 is a perspective view schematically illustrating an example of a punched product according to the present disclosure.

FIG. 5 is a cross-sectional view taken along line V-V illustrated in FIG. 4.

FIG. 6 is a cross-sectional view schematically illustrating a state in which an adhesive piece and a cover film covering the adhesive piece are picked up from a substrate film.

FIG. 7 is a cross-sectional view schematically illustrating a state of a producing process of the semiconductor module.

FIG. 8 is a graph showing temporal changes in shear viscosity of heat-curable resin compositions according to Examples and Comparative Examples.

### DESCRIPTION OF EMBODIMENTS

Hereinafter, embodiments of the present disclosure are described in detail with reference to the drawings. However, the present disclosure is not limited to the following embodiments. In the following embodiments, the components (including steps and the like) are not essential unless otherwise specified. In the following description, the same or corresponding parts are denoted by the same reference numerals, and redundant description is omitted. Further, unless otherwise specified, the positional relationship such as up, down, left, and right is based on the positional relationship illustrated in the drawings. The sizes of the components in the drawings are conceptual, and the dimensional ratios in the drawings are not limited to the illustrated ratios.

Numerical values and ranges thereof in the present specification are not intended to limit the present disclosure. In the present specification, a numerical range indicated using “to” indicates a range including numerical values described before and after “to” as a minimum value and a maximum value, respectively. In the numerical ranges described in stages in the present specification, the upper limit value or the lower limit value described in one numerical range may be replaced with the upper limit value or the lower limit value of the numerical range described in another stage. The description of “(meth)acrylic” in the present specification means “acrylic” and its corresponding “methacrylic”.

### <Layered Film>

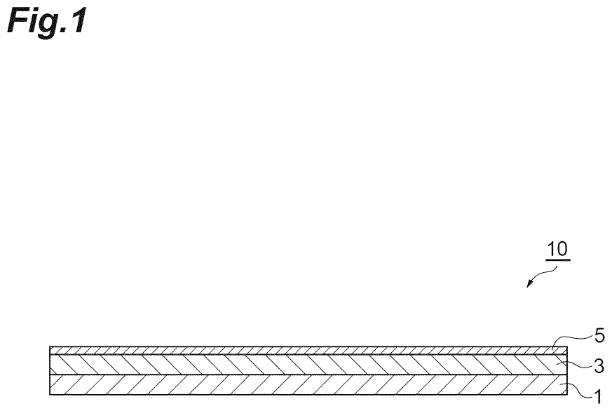

FIG. 1 is a cross-sectional view schematically showing a layered film according to the present embodiment. A layered film 10 shown in this drawing includes a substrate film 1, an adhesive layer 3, and a cover film 5 in this order. The layered film 10 has, for example, a width of 300 mm to 500 mm and a total length of 10 m to 400 m, and is produced by being wound in, for example, a roll shape. Hereinafter, the configuration of the layered film 10 will be described.

### [Substrate Film]

The substrate film 1 is not particularly limited as long as it can sufficiently withstand the tension applied in the producing process of the adhesive layer 3 and the producing process of the semiconductor module. The substrate film 1 is preferably transparent from the viewpoint of visibility of the adhesive layer 3 disposed thereon. As the substrate film 1, a polyester film such as a polyethylene terephthalate film, a polytetrafluoroethylene film, a polyethylene film, a polypropylene film, a polymethylpentene film, a polyvinyl acetate film, a polyolefin film such as a homopolymer or copolymer of a poly-4-methylpentene-1, an ethylene-vinyl acetate copolymer, an ethylene-ethyl acrylate copolymer, or a mixture thereof, a plastic film such as a polyvinyl chloride film or a polyimide film, or the like can be used. The substrate film 1 may have a single layer structure or a multilayer structure.

The thickness of the substrate film 1 may be appropriately selected within a range in which workability is not impaired, and may be, for example, 10 to 200 μm, 20 to 100 μm, or 25 to 80 μm. These thickness ranges are practically acceptable and economically effective.

In order to increase the sticking force of the adhesive layer 3 to the substrate film 1, the surface of the substrate film 1 may be subjected to a chemical or physical surface treatment such as corona treatment, chromic acid treatment, ozone exposure, flame exposure, high pressure electric shock exposure, or ionizing radiation treatment. As substrate film 1, a film made of a fluororesin and having low surface energy can also be used. Examples of such a film include A-63 (release treatment agent: modified silicone-based) manufactured by TOYOBO FILM SOLUTION LIMITED, and A-31 (release treatment agent: Pt-based silicone-based) manufactured by TOYOBO FILM SOLUTION LIMITED.

In order to prevent the sticking force of the adhesive layer 3 to the substrate film 1 from being excessively increased, a release layer composed of a release agent such as a silicone-based parting agent, a fluorine-based parting agent, or a long-chain alkyl acrylate-based parting agent may be formed on the surface of the substrate film 1.

The sticking force between substrate film 1 and adhesive layer 3 is, for example, 0.5 N/m or more. When the sticking force is 0.5 N/m or more, it is easy to prevent the adhesive layer 3 from being unintentionally peeled off from the substrate film 1 in the process of producing the layered film 10. The sticking force between the substrate film 1 and the adhesive layer 3 means 90° peel strength, and specifically means peel strength measured when a sample having a width of 20 mm and having the adhesive layer 3 formed on the substrate film 1 is prepared, and the adhesive layer is peeled off from the substrate film at a peeling rate of 50 mm/min at an angle of 90°.

### [Adhesive Layer]

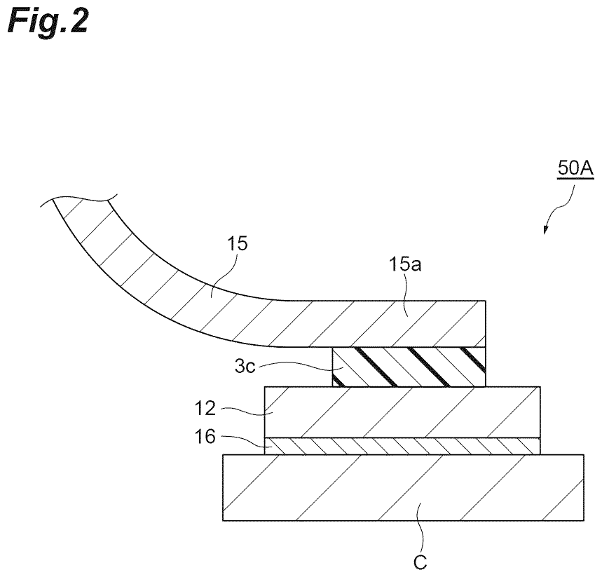

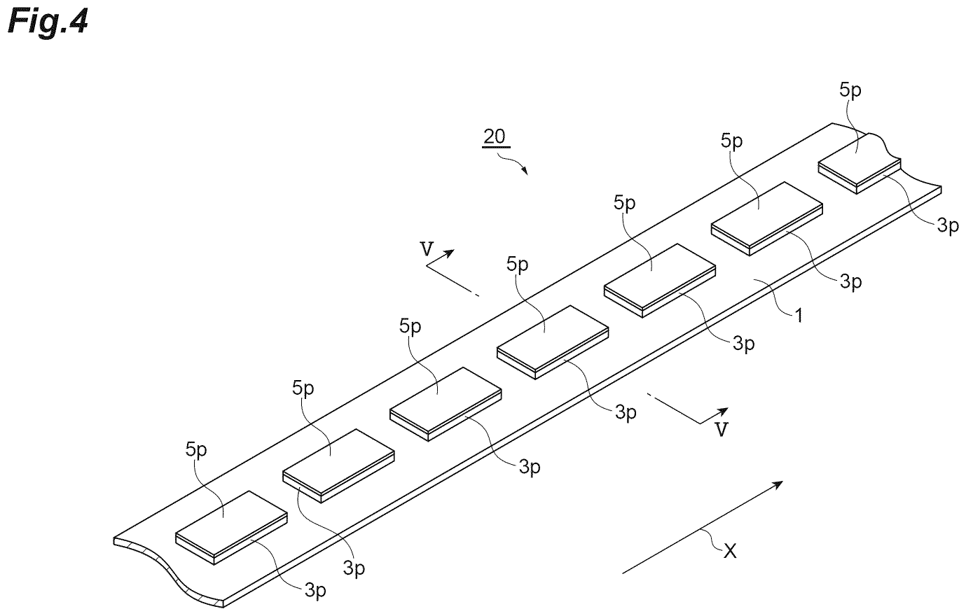

The adhesive layer 3 is used for adhesion between circuit members, and for example, is suitably used for adhesion between a printed circuit board and a tip part of a flexible printed circuit board (Hereinafter, the substrate is referred to as an “FPC substrate”.), or adhesion between a semiconductor chip and a tip part of the FPC board. A module 50A (connected structure) illustrated in FIG. 2 includes a semiconductor chip C, a printed circuit board 12 (first circuit member), an adhesive piece 3c, and an FPC board 15 (second circuit member). The adhesive piece 3c bonds the printed circuit board 12 and a tip part 15a of the FPC board 15. The adhesive piece 3c is formed of a cured product of the adhesive piece 3p (see FIG. 4). The adhesive piece 3p is obtained by processing the adhesive layer 3 illustrated in FIG. 1 into a predetermined shape by punching. An adhesive layer 16 bonds the printed circuit board 12 and the semiconductor chip C together. The adhesive layer 16 may have the same composition as or a different composition from that of the adhesive piece 3c.

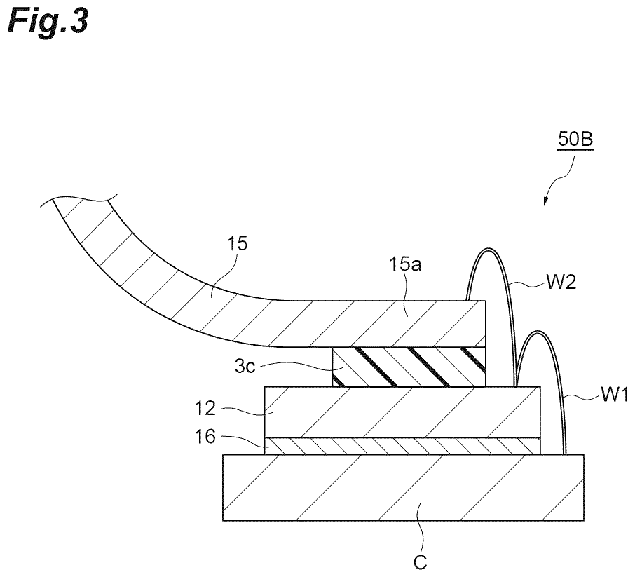

A module 50B illustrated in FIG. 3 is obtained by performing wire bonding on the module 50A illustrated in FIG. 2. A wire W1 electrically connects the semiconductor chip C and the printed circuit board 12, and a wire W2 electrically connects the printed circuit board 12 and the FPC board 15. The semiconductor chip C is, for example, a sensor chip. The printed circuit board 12 is for processing a signal from the semiconductor chip C. A signal from the printed circuit board 12 is transmitted to the tip part 15a of the FPC board 15.

An adhesive piece 3p (adhesive layer) is composed of a heat-curable adhesive composition that exhibits heat-curable properties by irradiation with radiation. That is, this composition contains a photocleavable compound cleaved upon irradiation with radiation to generate an amine compound, and a heat-curable resin cured upon heating in the presence of the amine compound.

Examples of the photocleavable compound include a compound having an α-aminoacetophenone skeleton. For example, the following compounds have an α-aminoacetophenone skeleton, and when irradiated with an ultraviolet ray, the compounds are deblocked to generate amine compounds having radicals. From such a viewpoint, the photocleavable compound may generate a radical by irradiation with an ultraviolet ray.

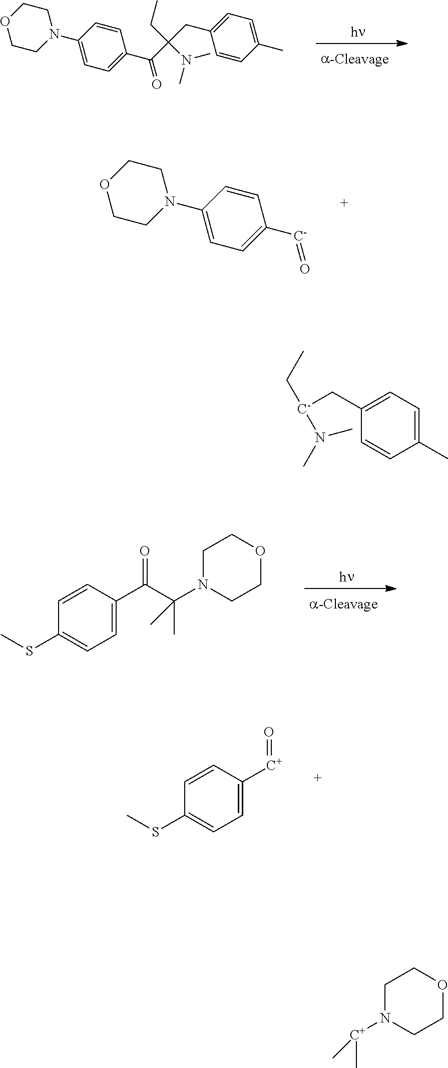

The heat-curable adhesive composition, for example, satisfies the following Condition 1:

### —Condition 1:

A storage elastic modulus at 75° C. is 3 MPa or more after ultraviolet irradiation under the conditions of an illuminance of 80 mW/cm² and an integrated light amount of 600 mJ/cm², and then heating at 75° C. for 3 hours.

It can be said that the heat-curable adhesive composition satisfying Condition 1 is excellent in low-temperature curability. As a result, there is an advantage that a member having relatively low heat resistance can be adopted as a member constituting the module 50B. In order to obtain the heat-curable adhesive composition satisfying Condition 1, for example, it is conceivable to use a phenol resin together with an epoxy resin as the heat-curable resin. The reason why the phenol resin contributes to the improvement of the low-temperature curability is that the reactivity between the phenol resin and the epoxy resin is higher than the reactivity between the epoxy resins, and the reaction easily proceeds by using the phenol resin.

By using the heat-curable adhesive composition that satisfies Condition 1, it is possible to reduce shaking of the adhesive piece 3c in the wire bonding step, and it is easy to perform wire bonding. As described above, the storage elastic modulus according to the condition 1 is 3 MPa or more, and may be 10 MPa or more, 15 MPa or more, or 30 MPa or more. The upper limit value of the storage elastic modulus according to the condition 1 is, for example, 200 MPa. The higher the storage elastic modulus according to condition 1, the easier it is to perform wire bonding.

The heat-curable adhesive composition may further satisfy the following Condition 2:

### —Condition 2:

A storage elastic modulus at 35° C. is 700 MPa or less after ultraviolet irradiation under the condition of an illuminance of 80 mW/cm² and an integrated light amount of 600 mJ/cm², and then heated at 75° C. for 3 hours.

By using the heat-curable adhesive composition that satisfies Condition 2, the internal stress of the adhesive piece 3c is easily relaxed, and the warpage of the module 50B can be suppressed. As described above, the storage elastic modulus under condition 2 is 700 MPa or less, and may be 50 to 700 MPa, 100 to 500 MPa, or 150 to 300 MPa.

In order to obtain a heat-curable adhesive composition that satisfies Condition 2, for example, the following method is considered.
Method 1: The amount of the thermoplastic resin (For example, acrylic rubber) contained in the heat-curable adhesive composition is relatively increased.
Method 2: A thermoplastic resin having a relatively low glass transition temperature (Tg) is used.
Method 3: A heat-curable resin having a flexible backbone is used.

According to the study of the present inventors, the Methods 1 and 2 are more effective than the Method 3. With regard to Method 1, when the heat-curable adhesive composition further contains a thermoplastic resin, the content of the thermoplastic resin may be, for example, 15 to 35 parts by mass or 15 to 30 parts by mass when a total mass of the heat-curable adhesive composition is 100 parts by mass. With respect to Method 2, the Tg of the thermoplastic resin is, for example, −50° C. to 20° C.

In the heat-curable adhesive composition, the curing reaction preferably proceeds to some extent by heat treatment at 75° C. for 3 hours. The extent to which the reaction is progressing can be quantified by differential scanning calorimetry. That is, it can be quantified by the reaction rate calculated by the following formula, and the calorific value C1 and the calorific value C2 are each obtained from a DSC curve obtained by differential scanning calorimetry at a heating rate of 10° C./min. The value of this reaction rate is, for example, 50% or more, and may be 60% or more or 70% or more.

$$Reaction rate ( \% ) = ( C 1 - C 2 ) / C 1 \times 100$$

The calorific value C1 is a calorific value of the resin composition after the heat-curable adhesive composition is irradiated with an ultraviolet ray under the conditions of an illuminance of 80 mW/cm² and an integrated light amount of 600 mJ/cm². The calorific value C2 is a calorific value of the resin composition after the heat-curable adhesive composition is irradiated with an ultraviolet ray under the conditions of an illuminance of 80 mW/cm² and an integrated light amount of 600 mJ/cm² and then heated at 75° C. for 3 hours. The temperature range of the differential scanning calorimetry is, for example, 30° C. to 300° C. The temperature range for obtaining the calorific values C1 and C2 from the DSC curve obtained by the measurement is 50° C. to 200° C. When the reaction rate is 50% or more, time degradation after the production step can be suppressed, and the reliability is excellent.

The melt viscosity of the heat-curable adhesive composition at 75° C. is, for example, 3000 to 12000 Pa·s, and may be 3500 to 10000 Pa·s or 4000 to 8000 Pa·s. When the melt viscosity at 75° C. is in the above range, the heat-curable adhesive composition can be disposed without any gap between the tip part 15a and the member to be bonded (printed circuit board 12) even if the tip part 15a of the FPC board 15 has irregularities. Even after the heat-curable adhesive composition is irradiated with radiation to exhibit the heat-curable properties of the composition, the melt viscosity may be in the above range. As a result, the tip part 15a and the printed circuit board 12 can be adhered with high strength. After the heat-curable adhesive composition is prepared and then stored for 4 weeks under the conditions of a temperature of 25° C. and a humidity of 55%, the melt viscosity at 75° C. is, for example, 20000 Pa·s or less, and may be 3000 to 16000 Pa·s or 4000 to 16000 Pa·s.

The layered film 10 is produced, for example, as follows. First, the raw material resin composition of the adhesive layer 3 is dissolved in a solvent such as an organic solvent to prepare a varnish coating liquid. After this coating liquid is applied onto substrate film 1, the solvent is removed to form the adhesive layer 3. Examples of the coating method include a knife coating method, a roll coating method, a spray coating method, a gravure coating method, a bar coating method, and a curtain coating method. Subsequently, the cover film 5 is bonded to the surface of the adhesive layer 3 under the conditions of normal temperature to 60° C. Thus, the layered film 10 can be obtained. After the adhesive layer 3 is formed on a wide substrate film, the cover film 5 is bonded to cover it to prepare a layered film, and the layered film is cut (slit) into a predetermined width to obtain the layered film 10.

### <Punched Product>

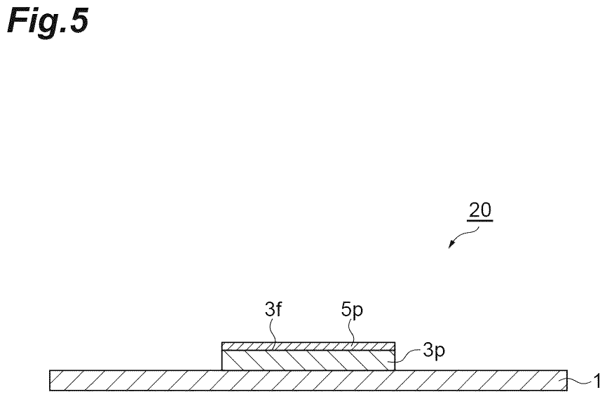

FIG. 4 is a perspective view schematically illustrating a punched product produced from the layered film 10. FIG. 5 is a cross-sectional view taken along line V-V illustrated in FIG. 4. A punched product 20 shown in these drawings includes a band-shaped substrate film 1 having a width of 100 mm or less, a plurality of adhesive pieces 3p, and a plurality of cover films 5p. The plurality of adhesive pieces 3p are disposed on the substrate film 1 so as to be aligned in the longitudinal direction (the direction of the arrow X shown in FIG. 4) thereof. The cover film 5p covers the upper surface 3f of the adhesive piece 3p and has the same shape as the adhesive piece 3p.

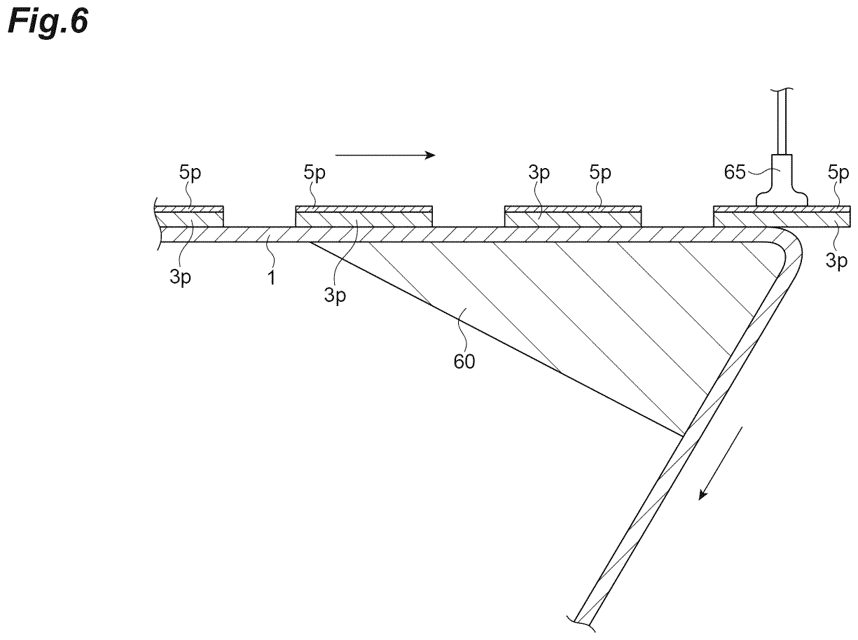

The adhesive piece 3p is suitably applied to adhesion between the circuit member (semiconductor chip or printed circuit board) and the tip part of the FPC board. The area of the adhesive piece 3p in planar view is, for example, 1 to 100 mm², and may be 3 to 50 mm² or 5 to 40 mm². According to the punched product 20, the plurality of adhesive pieces 3p disposed on the substrate film 1 so as to be aligned are sequentially picked up (see FIG. 6), and thereafter, each adhesive piece 3p can be disposed in a predetermined region of the circuit member, and the circuit member and the FPC member can be efficiently adhered.

The punched product 20 can be obtained, for example, through the following steps.
(a) preparing the layered film 10.
(b) punching the adhesive layer 3 and the cover film 5 in the layered film 10 to obtain a plurality of adhesive pieces 3p disposed on the substrate film 1 so as to be aligned in the longitudinal direction of the substrate film 1.

### <Heat-Curable Resin Composition>

The heat-curable adhesive composition constituting the adhesive layer 3 and the adhesive piece 3p is be described. As described above, the heat-curable adhesive composition contains a photocleavable compound cleaved upon irradiation with radiation to generate an amine compound, and a heat-curable resin cured upon heating in the presence of the amine compound. The composition may contain, for example, a thermoplastic resin and a filler in addition to these components. (Photocleavable compound)

The photocleavable compound is cleaved by irradiation with radiation to generate an amine compound. Examples of the photocleavable compound include compounds having an a-aminoacetophenone skeleton as described above. Examples of the compound include Omnirad 907 and Omnirad 379EG (both manufactured by IGM Resins B.V.). It is considered that Omnirad 379EG has an aliphatic amine having a high basicity, proton desorption from the phenol resin easily occurs, and a curing reaction easily proceeds. Omnirad is a registered trademark. As the photocleavable compound, a photoradical generator that generates a radical by irradiation with radiation or a photobase generator that generates a base may be used. Examples of the photobase generator include WPBG series manufactured by FUJIFILM Corporation, and more specific examples thereof include WPBG-027, WPBG-140, and WPBG-165.

### (Heat-Curable Resin)

The heat-curable resin is not particularly limited as long as it is a resin that is cured by heat. Examples of the heat-curable resin include an epoxy resin, an acrylic resin, a silicone resin, a phenol resin, a heat-curable polyimide resin, a polyurethane resin, a melamine resin, and a urea resin. These can be used singly or in combination of two or more kinds thereof.

The epoxy resin is not particularly limited as long as it is cured to have a heat resistance action. As the epoxy resin, a bifunctional epoxy resin such as bisphenol A-type epoxy, a novolac-type epoxy resin such as a phenol novolac-type epoxy resin or a cresol novolac-type epoxy resin, or the like can be used. As the epoxy resin, conventionally known epoxy resins such as a polyfunctional epoxy resin, a glycidylamine-type epoxy resin, a heterocyclic ring-containing epoxy resin, and an alicyclic epoxy resin can be used.

Examples of the bisphenol A-type epoxy resin include Epikote 807, Epikote 815, Epikote 825, Epikote 827, Epikote 828, Epikote 834, Epikote 1001, Epikote 1004, Epikote 1007 and Epikote 1009 (all manufactured by Mitsubishi Chemical Corporation), DER-330, DER-301 and DER-361 (all manufactured by The Dow Chemical Company), YD8125 and YDF8170 (all manufactured by Tohto Kasei Co., Ltd.), and the like.

Examples of the phenol novolak-type epoxy resin include Epikote 152 and Epikote 154 (all manufactured by Mitsubishi Chemical Corporation), EPPN-201 (manufactured by Nippon Kayaku Co., Ltd.), and DEN-438 (manufactured by The Dow Chemical Company).

Examples of the o-cresol novolac-type epoxy resin include YDCN-700-10 (manufactured by Nippon Steel Chemical & Materials Co., Ltd.), EOCN-102S, EOCN-103S, EOCN-104S, EOCN-1012, EOCN-1025, and EOCN-1027 (all manufactured by Nippon Kayaku Co., Ltd.), YDCN701, YDCN702, YDCN703, and YDCN704 (all manufactured by Tohto Kasei Co., Ltd.), and N-500P-10 (manufactured by DIC Corporation).

Examples of the polyfunctional epoxy resin include Epon 1031 S and 1032 H60 (all manufactured by Mitsubishi Chemical Corporation), Araldite 0163 (manufactured by BASF Japan Ltd.), Denacol EX-611, EX-614, EX-614B, EX-622, EX-512, EX-521, EX-421, EX-411, and EX-321 (all manufactured by Nagase ChemteX Corporation), and the like.

Examples of the amine-type epoxy resin include Epikote 604 (manufactured by Mitsubishi Chemical Corporation), YH-434 (manufactured by Tohto Kasei Co., Ltd.), TETRAD-X and TETRAD-C (all manufactured by MITSUBISHI GAS CHEMICAL COMPANY, INC.), and ELM-120 (manufactured by SUMITOMO CHEMICAL COMPANY, LIMITED).

Examples of the heterocyclic-containing epoxy resin include Araldite PT810 (manufactured by BASF Japan Ltd.), ERL4234, ERL4299, ERL4221, and ERL4206 (all manufactured by Union Carbide Corporation). These epoxy resins can be used singly or in combination of two or more kinds thereof.

As the epoxy resin, it is preferable to apply a polyfunctional epoxy resin having a small functional group equivalent. By applying the epoxy resin, the storage elastic modulus at 130° C. after the heat treatment of the adhesive film is improved, and the wire bonding property is excellent. Specific examples thereof include HP-4710 (manufactured by DIC Corporation), Epon 1031S, and 1032H60 (all manufactured by Mitsubishi Chemical Corporation).

As the epoxy resin curing agent that is a part of the heat-curable resin component, a commonly used known resin can be used. Specific examples thereof include amines a polyamide, an acid anhydride, a polysulfide, boron trifluoride, bisphenols having two or more phenolic hydroxyl groups in one molecule, such as bisphenol A, bisphenol F, and bisphenol S, and phenol resins such as a phenol novolak resin, a bisphenol A novolak resin, and a cresol novolak resin. As the epoxy resin curing agent, in particular, phenol resins such as a phenol novolac resin, a bisphenol A novolac resin, and a cresol novolac resin are preferable from the viewpoint of excellent electric corrosion resistance at the time of moisture absorption.

The epoxy curing agent may be used in combination with an epoxy resin or may be used singly.

Among the phenol resin curing agents, it is preferable to use PHENOLITE LF2882, PHENOLITE LF2822, PHENOLITE TD-2090, PHENOLITE TD-2149, PHENOLITE VH-4150, PHENOLITE VH4170 (All products manufactured by DIC Corporation), H-1 (trade name, manufactured by Meiwa Plastic Industries, Ltd.), EPICURE MP402FPY, EPICURE YL6065, EPICURE YLH129B65, Milex XL, Milex XLC, Milex XLC-LL, Milex RN, Milex RS, and Milex VR (All products manufactured by Mitsubishi Chemical Corporation, trade names).

The content of the heat-curable resin in the heat-curable adhesive composition may be, for example, 20 to 60 parts by mass or 20 to 50 parts by mass with respect to 100 parts by mass of the heat-curable adhesive composition. When the content of the heat-curable resin is within the above range, shrinkage of the adhesive layer 3 due to thermal curing can be suppressed, and excellent adhesion after thermal curing is easily achieved.

### (Thermoplastic Resin)

As the thermoplastic resin, a resin having thermoplasticity or a resin having thermoplasticity at least in an uncured state and forming a crosslinked structure after heating can be used. As the thermoplastic resin, a (meth)acrylic copolymer having a reactive group (Hereinafter, sometimes referred to as a “reactive group-containing (meth)acrylic copolymer”) is preferable from the viewpoint of excellent shrinkability, heat resistance, and peelability.

When a reactive group-containing (meth)acrylic copolymer is contained as the thermoplastic resin, the heat-curable adhesive composition may not contain the heat-curable resin. That is, an aspect may be employed in which a reactive group-containing (meth)acrylic copolymer, a curing accelerator, and a filler are contained. The thermoplastic resins can be used singly or in combination of two or more kinds thereof.

Examples of the (meth)acrylic copolymer include (meth)acrylic acid ester copolymers such as acrylic glass and acrylic rubber, and acrylic rubber is preferable. The acrylic rubber contains an acrylic acid ester as a main component, and is preferably formed by copolymerization of a monomer selected from a (meth)acrylic acid ester and acrylonitrile.

Examples of the (meth)acrylic acid ester include methyl acrylate, ethyl acrylate, propyl acrylate, isopropyl acrylate, butyl acrylate, isobutyl acrylate, hexyl acrylate, cyclohexyl acrylate, 2-ethylhexyl acrylate, lauryl acrylate, methyl methacrylate, ethyl methacrylate, propyl methacrylate, isopropyl methacrylate, butyl methacrylate, isobutyl methacrylate, hexyl methacrylate, cyclohexyl methacrylate, 2-ethylhexyl methacrylate, and lauryl methacrylate. As the (meth)acrylic acid ester copolymer, a copolymer containing butyl acrylate and acrylonitrile as copolymerization components and a copolymer containing ethyl acrylate and acrylonitrile as copolymerization components are preferable.

The reactive group-containing (meth)acrylic copolymer is preferably a reactive group-containing (meth)acrylic copolymer containing a (meth)acrylic monomer having a reactive group as a copolymerization component. Such a reactive group-containing (meth)acrylic copolymer can be obtained by copolymerizing a monomer composition containing a (meth)acrylic monomer having a reactive group and the above-mentioned monomer.

As the reactive group, an epoxy group, a carboxyl group, an acryloyl group, a methacryloyl group, a hydroxyl group, and an episulfide group are preferable from the viewpoint of improving heat resistance, and among them, an epoxy group and a carboxyl group are more preferable from the viewpoint of crosslinkability.

In the present embodiment, the reactive group-containing (meth)acrylic copolymer is preferably an epoxy group-containing (meth)acrylic copolymer containing a (meth)acrylic monomer having an epoxy group as a copolymerization component. In this case, examples of the (meth)acrylic monomer having an epoxy group include glycidyl acrylate, 4-hydroxybutyl acrylate glycidyl ether, 3,4-epoxycyclohexyl methyl acrylate, glycidyl methacrylate, 4-hydroxybutyl methacrylate glycidyl ether, and 3,4-epoxycyclohexyl methyl methacrylate. The (meth)acrylic monomer having a reactive group is preferably glycidyl acrylate or glycidyl methacrylate from the viewpoint of heat resistance.

The Tg of the thermoplastic resin is, for example, −50° C. to 20° C., and may be −40° C. to 10° C. or −40° C. to 0° C. When the Tg of the thermoplastic resin is −50° C. or higher, it is easy to suppress the adhesive layer 3 from becoming excessively soft, and excellent handleability and adhesiveness can be achieved. On the other hand, when the Tg of the thermoplastic resin is 0° C. or lower, the flexibility of the adhesive layer 3 is easily secured, and excellent adhesive strength can be achieved. In addition, even when irregularities are present on the surface of the adherend, the adhesive layer 3 easily follows the irregularities, and excellent adhesiveness can be exhibited.

The Tg of the thermoplastic resin is a midpoint glass transition temperature value obtained by differential scanning calorimetry (DSC). Specifically, the Tg of the thermoplastic resin is an intermediate point glass transition temperature calculated by a method in accordance with JIS K7121: 1987 by measuring a heat quantity change under the conditions of a heating rate of 10° C./min and a measurement temperature of −80 to 80° C. When the thermoplastic resin is a commercially available product, values described in a catalog or the like may be adopted.

The weight average molecular weight of the thermoplastic resin is preferably 100000 or more and 2 million or less. When the weight average molecular weight is 100000 or more, heat resistance is easily secured. On the other hand, when the weight average molecular weight is 2 million or less, it is easy to suppress a decrease in flow and a decrease in stickability. The weight average molecular weight of the thermoplastic resin may be 400000 or more and 2 million or less or 500000 or more and 2 million or less. The weight average molecular weight is a value in terms of polystyrene using a calibration curve by standard polystyrene by gel permeation chromatography (GPC).

When the (meth)acrylic copolymer having a reactive group contains glycidyl acrylate or glycidyl methacrylate as a copolymerization component, the content of the thermoplastic resin is preferably 20 to 40 parts by mass when the mass of the entire adhesive film is 100 parts by mass. When the content is within the above range, the flexibility and adhesiveness of the adhesive layer 3 are easily achieved at a higher level. As the (meth)acrylic copolymer having a reactive group as described above, a copolymer obtained by a polymerization method such as pearl polymerization or solution polymerization may be used. Alternatively, a commercially available product such as SG-P3 (trade name: manufactured by Nagase ChemteX Corporation) may be used.

### (Inorganic Filler)

The heat-curable adhesive composition may contain an inorganic filler. Examples of the inorganic filler include metal fillers such as silver powder, gold powder, and copper powder, and nonmetal inorganic fillers such as silica, alumina, boron nitride, titania, glass, iron oxide, and ceramic. The inorganic filler can be selected according to a desired function.

The inorganic filler may have an organic group on the surface. Since the surface of the inorganic filler is modified with an organic group, dispersibility in an organic solvent when preparing a varnish for forming the adhesive layer 3 can be improved. In addition, shrinkage associated with thermal curing of the adhesive layer 3 can be suppressed, and it is easy to achieve both high elastic modulus and excellent peelability of the adhesive layer 3. The inorganic filler having an organic group on the surface can be obtained, for example, by mixing a silane coupling agent represented by the following formula (B-1) with an inorganic filler and stirring the mixture at a temperature of 30° C. or higher. The fact that the surface of the inorganic filler is modified with an organic group can be confirmed by UV measurement, IR measurement, XPS measurement, or the like.

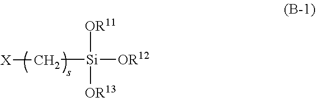

In the formula (B-1), X represents an organic group selected from the group consisting of a phenyl group, a glycidoxy group, an acryloyl group, a methacryloyl group, a mercapto group, an amino group, a vinyl group, an isocyanate group and a methacryloxy group, s represents an integer of 0 or 1 to 10, and R11, R12 and R13 each independently represent an alkyl group having 1 to 10 carbon atoms.

Examples of the alkyl group having 1 to 10 carbon atoms include a methyl group, an ethyl group, a propyl group, a butyl group, a pentyl group, a hexyl group, a heptyl group, an octyl group, a nonyl group, a decyl group, an isopropyl group, and an isobutyl group. The alkyl group having 1 to 10 carbon atoms is preferably a methyl group, an ethyl group, or a pentyl group from the viewpoint of easy availability.

X is preferably an amino group, a glycidoxy group, a mercapto group, or an isocyanate group, more preferably a glycidoxy group or a mercapto group, from the viewpoint of heat resistance. In the formula (B-1), s is preferably 0 to 5, more preferably 0 to 4, from the viewpoint of suppressing the film fluidity at high temperature and improving the heat resistance.

Examples of the silane coupling agent include trimethoxyphenylsilane, dimethyldimethoxyphenylsilane, triethoxyphenylsilane, dimethoxymethylphenylsilane, vinyltrimethoxysilane, vinyltriethoxysilane, vinyltris (2-methoxyethoxy)silane, N-(2-aminoethyl)-3-aminopropylmethyldimethoxysilane, N-(2-aminoethyl)-3-aminopropyltrimethoxysilane, 3-aminopropyltriethoxysilane, 3-aminopropyltrimethoxysilane, 3-glycidoxypropyltrimethoxysilane, 3-glycidoxypropylmethyldimethoxysilane, 2-(3,4-epoxycyclohexyl)ethyltrimethoxysilane, 3-isocyanatopropyltriethoxysilane, 3-methacryloxypropyltrimethoxysilane, 3-mercaptopropyltrimethoxysilane, 3-ureidopropyltriethoxysilane, N-(1,3-dimethylbutylidene)-3-(triethoxysilyl)-1 propanamine, N,N′-bis(3-(trimethoxysilyl) propyl)ethylenediamine, polyoxyethylenepropyltrialkoxysilane, polyethoxydimethylsiloxane, and the like.

Among them, 3-aminopropyltriethoxysilane, 3-glycidoxypropyltrimethoxysilane, 3-isocyanatopropyltriethoxysilane, and 3-mercaptopropyltrimethoxysilane are preferable, and trimethoxyphenylsilane, 3-glycidoxypropyltrimethoxysilane, and 3-mercaptopropyltrimethoxysilane are more preferable. The silane coupling agent can be used singly or in combination of two or more kinds thereof.

The content of the coupling agent is, for example, 0 to 10 parts by mass and may be 0.1 to 5 parts by mass with respect to 100 parts by mass of the heat-curable adhesive composition from the viewpoint of balancing heat resistance and storage stability, and the upper limit value may be 3 parts by mass from the viewpoint of storage stability.

The content of the inorganic filler is, for example, 20 to 35 parts by mass and may be 25 to 35 parts by mass with respect to 100 parts by mass of the heat-curable adhesive composition. The content of the inorganic filler in the heat-curable adhesive composition may be, for example, 300 parts by mass or less, 200 parts by mass or less, or 150 parts by mass or less with respect to 100 parts by mass of the thermoplastic resin. The lower limit of the content of the inorganic filler is not particularly limited, but may be, for example, 10 parts by mass or more and 50 parts by mass or more with respect to 100 parts by mass of the thermoplastic resin. By setting the content of the inorganic filler within the above range, shrinkage associated with thermal curing can be suppressed, and it is easy to achieve both high melt viscosity and excellent peelability of the adhesive layer 3.

### (Organic Filler)

The heat-curable adhesive composition may contain an organic filler. Examples of the organic filler include carbon, rubber-based fillers, silicone-based fine particles, polyamide fine particles, and polyimide fine particles. The content of the organic filler is, for example, 450 parts by mass or less, and may be 400 parts by mass or less or 350 parts by mass or less with respect to 100 parts by mass of the thermoplastic resin. The lower limit of the content of the organic filler is not particularly limited, but is, for example, 10 parts by mass or more with respect to 100 parts by mass of the thermoplastic resin.

### (Organic Solvent)

The heat-curable adhesive composition may be diluted using an organic solvent as necessary. The organic solvent is not particularly limited, but can be determined in consideration of volatility and the like during film formation from the boiling point. Specifically, a solvent having a relatively low boiling point, such as methanol, ethanol, 2-methoxyethanol, 2-ethoxyethanol, 2-butoxyethanol, methyl ethyl ketone, acetone, methyl isobutyl ketone, toluene, or xylene, is preferable from the viewpoint that curing of the film hardly proceeds during film formation. For the purpose of, for example, improving film formability, it is preferable to use a solvent having a relatively high boiling point, such as dimethylacetamide, dimethylformamide, N-methylpyrrolidone, or cyclohexanone. These solvents can be used singly or in combination of two or more kinds thereof.

The thickness of the adhesive layer 3 may be appropriately selected as long as workability is not impaired, and may be, for example, 1 to 200 μm, 5 to 150 μm, or 10 to 150 μm. When the thickness of the adhesive layer 3 is 1 μm or more, sufficient adhesiveness is easily secured, and on the other hand, when the thickness is 200 μm or less, it is easy to suppress protrusion of the heat-curable adhesive composition constituting the adhesive layer 3 from the substrate film 1 or the cover film 5.

### [Cover Film]

The cover film 5 may be any film as long as it can be easily peeled off from the adhesive layer 3. As the cover film 5, a polyester film such as a polyethylene terephthalate film, a polytetrafluoroethylene film, a polyethylene film, a polypropylene film, a polymethylpentene film, a polyvinyl acetate film, a polyolefin film such as a homopolymer or copolymer of a poly-4-methylpentene-1, an ethylene-vinyl acetate copolymer, an ethylene-ethyl acrylate copolymer, or a mixture thereof, a plastic film such as a polyvinyl chloride film or a polyimide film, or the like can be used. The cover film 5 may have a single layer structure or a multilayer structure. In the case of a multilayer structure, a tacky film may be used, and specifically, a tacky film for dicing (manufactured by Maxell Corporation) is preferable. The tacky film may have a tacky layer and a substrate layer. In this case, the tacky layer may be configured to be in contact with the adhesive layer 3. As the tacky layer, a photocurable tacky layer or a pressure sensitive adhesive layer can be used, and as the substrate layer, the plastic film or the like can be used.

The sticking force between the adhesive layer 3 and the cover film 5 is, for example, 70 N/m or less, may be 50 N/m or less, or may be 20 N/m or less. In particular, when the adhesive layer 3 is made of a resin composition having heat-curable properties, the sticking force of the cover film 5 to the adhesive layer 3 after heat treatment at 75° C. for 1 second is preferably in the above range. When the sticking force is 70 N/m or less, the adhesive layer 3 covered with the cover film 5 is temporarily contact-bonded to an adherend (for example, a substrate) at 75° C. for 0.5 seconds, and then the cover film 5 can be easily peeled off from the semi-cured adhesive layer 3 with a tacky tape or the like. The sticking force of the cover film 5 to the adhesive layer 3 means a 90° peel strength, and specifically means a peel strength measured when a sample in which a cover film having the same width as that of the adhesive layer 3 is disposed on an adhesive layer having the same composition as that of the adhesive layer 3 and having a width of 20 mm is prepared, and the cover film is peeled off from the adhesive layer at an angle of 90° at a peeling rate of 50 mm/min. When the cover film 5 is a tacky film having a photocurable tacky layer, the sticking force may be a value after light irradiation.

The thickness of the cover film 5 may be appropriately selected as long as workability is not impaired, and may be, for example, 10 to 200 μm, 10 to 180 μm, or 15 to 140 μm. These thickness ranges are practically acceptable and economically effective.

### <Method for Producing Semiconductor Module>

A method for manufacturing the module 50B (connected structure) illustrated in FIG. 3 using the punched product 20 is described. FIG. 6 is a cross-sectional view schematically showing a state in which an adhesive piece 3p and a cover film 5p covering the adhesive piece 3p are picked up from the substrate film 1. While a constant tension is applied to the punched product 20, the punched product 20 is moved in the direction of the arrow shown in FIG. 6 while the surface of the punched product 20 on the substrate film 1 side is brought into contact with the wedge-shaped member 60. As a result, as shown in the drawing, the front of the adhesive piece 3p and the cover film 5p is lifted from the substrate film 1. In this state, for example, the adhesive piece 3p and the cover film 5p are picked up by a pickup device 65 having a suction force.

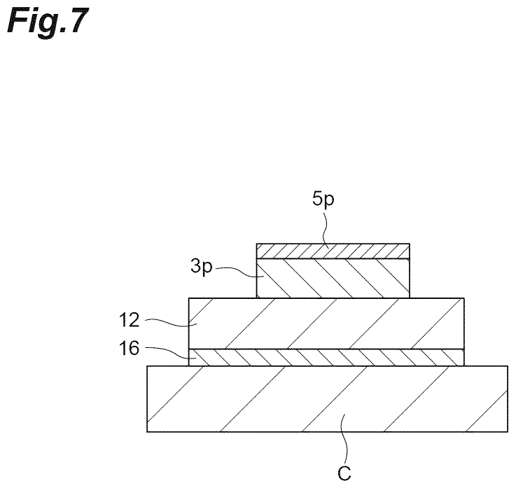

Next, the adhesive piece 3p covered with the cover film 5p is disposed on the surface of the printed circuit board 12 (see FIG. 7). For example, in this state, the adhesive piece 3p is irradiated with an ultraviolet ray. The illuminance of the ultraviolet ray may be, for example, 10 to 200 mW/cm². The integrated light amount of the ultraviolet ray may be, for example, 300 to 900 mJ/cm². Thereafter, the adhesive piece 3p is temporarily contact-bonded to the printed circuit board 12. The temporary contact bonding may be performed, for example, for 0.1 to 10 seconds under the conditions of a temperature of 60 to 85° C. and a pressing force of 0.1 to 2 MPa. By the temporary contact bonding, the adhesive piece 3p is semi-cured, so that the adhesive force to the surface of the printed circuit board 12 is improved. Thereafter, the cover film 5p is peeled off from the adhesive piece 3p using a tacky tape or the like. As a result, the surface of the adhesive piece 3p is exposed.

The adhesion of the tip part 15a of the FPC board 15 to the printed circuit board 12 includes a step of contact bonding the tip part 15a to the adhesive piece 3p, and then a step of curing the adhesive piece 3p by heating. That is, first, the tip part 15a of the FPC board 15 is disposed on the upper surface 3f of the adhesive piece 3p, and then the tip part 15a is contact-bonded to the adhesive piece 3p. As a result, a layered body including the printed circuit board 12, the FPC board 15, and the adhesive piece 3p is obtained (step (A)). The contact bonding may be performed for 0.1 to 10 seconds under conditions of a temperature of 60 to 85° C. and a pressing force of 0.1 to 3 MPa, for example.

Next, the adhesive piece 3p is cured. The curing treatment may be performed, for example, at a temperature of 65 to 85° C. for 30 to 240 minutes. Thus, the module 50A illustrated in FIG. 2 is obtained (step (B)).

From the viewpoint of the heat resistance of the members constituting the module 50A, the heating condition in the conditions 1 and 2 is set to 75° C. for 3 hours. By setting the temperature at which the module 50A is heated to be relatively low, there is an advantage that choices of materials are widened.

Wire bonding is performed on the module 50A (step (C)). Thus, the module 50B illustrated in FIG. 3 is obtained. Thereafter, the semiconductor module is completed through processing of protecting the wires W1 and W2 of the module 50B with a resin material, heat treatment in which a curing reaction of the adhesive piece 3c proceeds, and the like. Note that an adhesive piece already irradiated with radiation may be used for producing the connected structure. When the connected structure is produced using the adhesive piece, the step (A), the step (B), and the step (C) may be sequentially performed.

Although the embodiments of the present disclosure have been described in detail above, the present disclosure is not limited to the above embodiments. For example, in the above embodiment, the case where the adhesive piece 3p made of the adhesive composition is prepared in advance by punching has been exemplified, but the adhesive layer may be formed by preparing a coating liquid containing the adhesive composition and applying the coating liquid onto the surface of the printed circuit board 12.

### EXAMPLES

Hereinafter, the present disclosure is described based on examples. The present disclosure is not limited to the following examples.

In order to prepare adhesive varnishes of Examples and Comparative Examples, the following materials were prepared.

### <Epoxy Resin (Heat-Curable Resin)>

EXA-830CRP (trade name, bisphenol F-type epoxy resin manufactured by DIC Corporation, epoxy equivalent: 160 g/eq, liquid)

### <Phenol Resin (Heat-Curable Resin)>

MEH-7800-4 S (trade name: xylylene-type phenol resin, manufactured by Meiwa Chemical Co., Ltd., hydroxyl group equivalent: 170 g/eq)

### <Thermoplastic Resin>

HTR-860P-3CSP (trade name: manufactured by Nagase ChemteX Corporation, acrylic resin, weight average molecular weight: 800000, Tg: 12° C.)

### <Photocleavable Compound>

Omnirad379EG (trade name: manufactured by IGM Resins B.V.)

### <Curing Accelerator>

CUREZOL 2PZ-CN (trade name: 1-cyanoethyl-2 phenylimidazole, “CUREZOL” manufactured by SHIKOKU CHEMICALS CORPORATION, registered trademark)

### <Filler>

SC-2050-HLG (trade name, manufactured by ADMATECHS COMPANY LIMITED surface-treated filler)

### <Solvent>

Cyclohexanone

### Example 1

A material shown in Example 1 in Table 1 and a solvent were mixed and vacuum-degassed to obtain an adhesive varnish. This adhesive varnish was applied onto a surface release-treated PET film (substrate film) having a thickness of 38 μm. A film-shaped adhesive (adhesive layer) having a thickness of 25 μm was formed on one surface of the PET film through the drying step. A tacky film for dicing (manufactured by Maxell Co., Ltd.) was attached to the surface of the film-shaped adhesive to obtain a layered film.

### Example 2 to 5 and Comparative Example 1 to 4

A layered film was produced in the same manner as in Example 1 except that the adhesive varnish having the composition shown in Examples 2 to 5 and Comparative Examples 1 to 4 in Tables 1 and 2 was used.

The following items were evaluated for the film-shaped adhesives according to Examples and Comparative Examples.

### (Measurement of Peel Strength)

The peel strength of the film-shaped adhesive was measured by the following method. First, the layered film was punched into a size of 3.2 mm×3.2 mm. After the substrate film was peeled off from the layered film, the film-shaped adhesive was attached to an organic substrate, and temporarily contact-bonded on a stage at 75° C. at a pressure of 1.0 N for 0.5 seconds. Next, the cover film was peeled off from the film-shaped adhesive, and a polyimide film (UPILEX 50S (trade name), manufactured by Ube Industries, Ltd.) having a size of 5 mm×100 mm was attached to the film-shaped adhesive, and contact-bonded on a stage at 75° C. with a force of 15 N for 1 second. Thereafter, the film-shaped adhesive was cured by heating at 75° C. for 3 hours to obtain a measurement sample. The peel strength was measured with a 90 degree peel tester (manufactured by TESTER SANGYO CO., LTD.) at a test speed of 50 mm/min. The results are shown in Tables 1 and 2.

### (Measurement of Calorific Value)

The reaction rate of the film-shaped adhesive was measured by the following method. That is, the film-shaped adhesive was irradiated with an ultraviolet ray under the conditions of an illuminance of 80 mW/cm² and an integrated light amount of 600 mJ/cm². 10 mg of the film-shaped adhesive after ultraviolet irradiation was weighed on an aluminum pan (manufactured by Epolead Service Inc.), and the aluminum pan was covered with an aluminum lid, and the evaluation sample was sealed in the sample pan using a crimper. DSC was measured at a heating rate of 10° C./min and a measurement temperature range of 30 to 300° C. in a nitrogen atmosphere using a differential scanning calorimeter (Thermo plus DSC8235E, manufactured by Rigaku Corporation). As a means for analyzing the calorific value, a partial area analysis method was used. The total calorific value (unit: J/g) was calculated by assigning a baseline of the analysis temperature range and integrating the peak area by giving an analysis instruction in the temperature range of 50° C. to 200° C. of the DSC curve. This was defined as an initial calorific value C1.

The film-shaped adhesives (initial samples) obtained in Examples and Comparative Examples were placed in an oven set at 75° C. and heat-treated for 3 hours. Using the heat-treated sample, the calorific value (unit: J/g) at 50° C. to 200° C. was calculated in the same procedure as before the heat treatment. This was defined as a calorific value C2 after the heat treatment. Using the obtained values of the two calorific values C1 and C2, the reaction rate was calculated by the following formula. The results are shown in Tables 1 and 2.

$$Reaction rate ( \% ) = ( C 1 - C 2 ) / C 1 \times 100$$

### (Measurement of Melt Viscosity)

The film-shaped adhesive was irradiated with an ultraviolet ray under the conditions of an illuminance of 80 mW/cm² and an integrated light amount of 600 mJ/cm². The melt viscosity at 75° C. of the film-shaped adhesive after irradiation with an ultraviolet ray (B-stage state before heating at 75° C. for 3 hours) was measured by the following method. That is, a plurality of film-shaped adhesives having a thickness of 25 μm were layered body to have a thickness of about 300 μm, and this layered body was punched with a q 9 mm punch to prepare a sample. A circular aluminum plate jig having a diameter of 8 mm was installed in a dynamic viscoelasticity apparatus ARES (manufactured by TA instruments), and the sample was further set therein. Thereafter, measurement was performed while raising the temperature to 100° C. at a heating rate of 5° C./min while applying a strain of 5% at 35° C. The frequency was kept constant at 1 Hz, the initial load was held at 300 g, and the axial force was held at 100 g. The values of the melt viscosity at 75° C. are shown in Tables 1 and 2.

### (Measurement of Storage Elastic Modulus)

The film-shaped adhesive was irradiated with an ultraviolet ray under the conditions of an illuminance of 80 mW/cm² and an integrated light amount of 600 mJ/cm². The film-shaped adhesive after ultraviolet irradiation was heated at 75° C. for 3 hours, and then the storage elastic modulus of the film-shaped adhesive was measured by the following method. That is, a plurality of film-shaped adhesives having a thickness of 25 μm was layered to have a thickness of about 300 μm, and this was made into a size of width 4 mm×33 mm, and cured at 75° C. for 3 hours to obtain a sample for measurement. A sample was set in a dynamic viscoelasticity apparatus (Product name: Rheogel E-4000, manufactured by UBM Co., Ltd.) at a distance between chucks of 20 mm, a tensile load was applied thereto, measurement was performed at a frequency of 10 Hz and a heating rate of 3° C./min, and storage elastic moduli at 35° C. and 75° C. were measured. The results are shown in Tables 1 and 2.

TABLE 1

| | | | Example | Example | Example | Example | Example |
|---|---|---|---|---|---|---|---|
| | | | 1 | 2 | 3 | 4 | 5 |
| Resin | Epoxy resin | EXA-830CRP | 110 | 110 | 90 | 100 | 90 |
| component | Phenol resin | MEH-7800-4S | 100 | 100 | 90 | 90 | 80 |
| [parts by | Thermoplastic | HTR-860P- | 100 | 100 | 100 | 100 | 100 |
| mass] | resin | 3CSP | | | | | |

| | | | | | | |
|---|---|---|---|---|---|---|
| Photocleavable compound | Omnirad | 1.5 | 0.7 | 0.7 | 0.7 | 0.8 |
| [parts by mass] | 379EG | | | | | |
| Filler [parts by mass] | SC-2050-HLG | 130 | 130 | 120 | 110 | 90 |

| | | | | | |
|---|---|---|---|---|---|
| Peel strength [N/m] | 120 | 60 | 350 | 330 | 370 |
| Reaction rate [%] | 80 | 60 | 60 | 70 | 70 |
| Melt viscosity at 75° C. [Pa · s] | 4500 | 3900 | 6500 | 5800 | 6700 |
| Elastic modulus after curing at 35° C. [MPa] | 1100 | 900 | 500 | 400 | 300 |
| Elastic modulus after curing at 75° C. [MPa] | 160 | 20 | 40 | 30 | 20 |

TABLE 2

| | | | Comparative | Comparative | Comparative | Comparative |
|---|---|---|---|---|---|---|
| | | | Example 1 | Example 2 | Example 3 | Example 4 |
| Resin | Epoxy resin | EXA-830CRP | 110 | 110 | 80 | 110 |
| component | Phenol resin | MEH-7800-4S | 100 | 100 | 70 | 100 |
| [parts by | Thermoplastic | HTR-860P- | 100 | 100 | 100 | 100 |
| mass] | resin | 3CSP | | | | |

| | | | | | |
|---|---|---|---|---|---|
| Curing accelerator | 2PZ-CN | 0.3 | 0.2 | 0.2 | 0.1 |
| [parts by mass] | | | | | |
| Filler [parts by mass] | SC-2050-HLG | 130 | 130 | 110 | 130 |

| | | | | |
|---|---|---|---|---|
| Peel strength [N/m] | 250 | 150 | 440 | 170 |
| Reaction rate [%] | 70 | 60 | 60 | 30 |
| Melt viscosity at 75° C. [Pa · s] | 4300 | 3800 | 6800 | 4900 |
| Elastic modulus after curing at 35° C. [MPa] | 1100 | 900 | 400 | 40 |
| Elastic modulus after curing at 75° C. [MPa] | 370 | 20 | 20 | 0.2 |

### (Evaluation of Temporal Change in Shear Viscosity)

For the film-shaped adhesives according to Examples 1, 2, and 4 and Comparative Examples 1, 2, and 4, the shear viscosity at 75° C. was measured every week. That is, eight test pieces having a predetermined size cut out from the film adhesive were prepared. These were layered body on a hot plate at 70° C. using a rubber roll to prepare a layered body having a thickness of 300 μm. This layered body was punched with a q 9 mm punch to prepare a sample. The sample was mounted on a measurement jig of a rotary viscoelasticity measuring device (manufactured by TA Instruments Japan Inc., trade name: ARES-RDA). At this time, the gap of the measurement jig was adjusted so that the load applied to the sample was 10 to 15 g. Subsequently, the viscoelasticity of the sample was measured under the following conditions.

### Measurement Conditions:

Disk plate: made of aluminum, circular (8 mm φ)
Measurement frequency: 1 Hz
Heating rate: 5° C./min
Strain: 5%
Measurement temperature: 35 to 100° C.
Initial load: 300 g

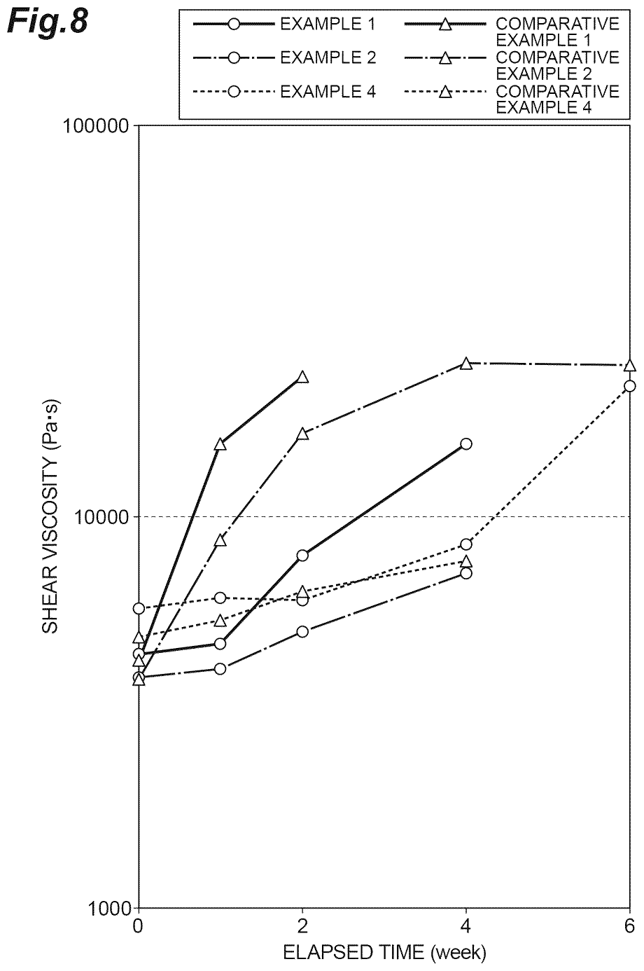

The measurement was continued for 6 weeks, and the measurement was terminated when the shear viscosity reached 20,000 Pa·s. The results are shown in FIG. 8. The film-shaped adhesive according to Examples was stored in a state of not being irradiated with an ultraviolet ray until the measurement was performed, and the film-shaped adhesive immediately before the measurement was irradiated with an ultraviolet ray. The ultraviolet ray was irradiated under the conditions of an illuminance of 80 mW/cm² and an integrated light amount of 600 mJ/cm².

### REFERENCE SIGNS LIST

1: Substrate film, 3: Adhesive layer, 3c, 3p: Adhesive piece, 5, 5p: Cover film, 10: Layered film, 12: Printed circuit board, 15: Flexible printed circuit board, 15a: Tip part, 20: Punched product, 50A, 50B: Module (connected structure), C: Semiconductor chip, W1, W2: Wire

1. A heat-curable adhesive composition comprising:
a photocleavable compound that generates an amine compound through cleavage induced by irradiation; and
a heat-curable resin that cures upon heating in a presence of the amine compound.

2. The heat-curable adhesive composition according to claim 1, wherein the photocleavable compound has an α-aminoacetophenone skeleton.

3. The heat-curable adhesive composition according to claim 1, wherein the heat-curable adhesive composition has a storage elastic modulus of 3 MPa or more at 75° C. after being irradiated with an ultraviolet ray under conditions of an illuminance of 80 mW/cm² and an integrated light amount of 600 mJ/cm² and then heated at 75° C. for 3 hours.

4. The heat-curable adhesive composition according to claim 1, wherein the heat-curable adhesive composition has a storage elastic modulus of 700 MPa or less at 35° C. after being irradiated with an ultraviolet ray under conditions of an illuminance of 80 mW/cm² and an integrated light amount of 600 mJ/cm² and then heated at 75° C. for 3 hours.

5. The heat-curable adhesive composition according to claim 1, wherein a reaction rate calculated by substituting calorific values C1 and C2, obtained from a DSC curve in a temperature range of 50 to 200° C. using differential scanning calorimetry at a heating rate of 10° C./min, into a following formula is 50% or more:
reaction rate (%)=(C1−C2)/C1×100
wherein C1 represents a calorific value of a resin composition after the heat-curable adhesive composition is irradiated with an ultraviolet ray under conditions of an illuminance of 80 mW/cm² and an integrated light amount of 600 mJ/cm², and
C2 represents a calorific value as a measurement target of a resin composition after the heat-curable adhesive composition is irradiated with an ultraviolet ray under conditions of an illuminance of 80 mW/cm² and an integrated light amount of 600 mJ/cm² and then heated at 75° C. for 3 hours.

6. The heat-curable adhesive composition according to claim 1, wherein a melt viscosity at 75° C. is 3000 to 12000 Pa·s.

7. The heat-curable adhesive composition according to claim 1, wherein a melt viscosity at 75° C. is 20000 Pa·s or less after being stored for 4 weeks under conditions of a temperature of 25° C. and a humidity of 55%.

8. The heat-curable adhesive composition according to claim 1, further comprising a thermoplastic resin,
wherein a content of the thermoplastic resin is 15 to 35 parts by mass when a total mass of the heat-curable adhesive composition is 100 parts by mass.

9. The heat-curable adhesive composition according to claim 8, wherein the thermoplastic resin has a glass transition temperature in a range of −50° C. to 20° C.

10. The heat-curable adhesive composition according to claim 1, further comprising an inorganic filler,
wherein a content of the inorganic filler is 20 to 35 parts by mass when a total mass of the heat-curable adhesive composition is 100 parts by mass.

11. A heat-curable adhesive composition obtained by irradiating the heat-curable adhesive composition according to claim 1 with radiation,
wherein the obtained heat-curable adhesive composition comprises the amine compound and the heat-curable resin.

12. A layered film comprising:
a substrate film; and
an adhesive layer provided on a surface of the substrate film,
wherein the adhesive layer is composed of the heat-curable adhesive composition according to claim 1.

13. A method for producing a connected structure, the method comprising following steps in order:
(A) preparing a layered body including a first circuit member, a second circuit member, and an adhesive layer disposed between the first circuit member and the second circuit member;
(B) heating the layered body at 65 to 85° C. for 30 to 240 minutes; and
(C) wire bonding the first circuit member and the second circuit member,
wherein the adhesive layer is composed of the heat-curable adhesive composition according to claim 1, and
the method further comprises a step of irradiating the adhesive layer with radiation before the step (B).

14. A method for producing a connected structure, the method comprising following steps in order:
(A) preparing a layered body including a first circuit member, a second circuit member, and an adhesive layer disposed between the first circuit member and the second circuit member;
(B) heating the layered body at 65 to 85° C. for 30 to 240 minutes; and
(C) wire bonding the first circuit member and the second circuit member,
wherein the adhesive layer is composed of the heat-curable adhesive composition according to claim 11.

15. The method for producing a connected structure according to claim 13, wherein the first circuit member is one selected from the group consisting of a printed circuit board and a semiconductor chip, and the second circuit member is a flexible printed circuit board.

16. A connected structure comprising:
a first circuit member;
a second circuit member; and
an adhesive layer disposed between the first circuit member and the second circuit member,
wherein the adhesive layer is composed of a cured product of the heat-curable adhesive composition according to claim 1.

17. A layered film comprising:
a substrate film; and
an adhesive layer provided on a surface of the substrate film,
wherein the adhesive layer is composed of the heat-curable adhesive composition according to claim 11.

18. The method for producing a connected structure according to claim 14, wherein the first circuit member is one selected from the group consisting of a printed circuit board and a semiconductor chip, and the second circuit member is a flexible printed circuit board.

19. A connected structure comprising:
a first circuit member;
a second circuit member; and
an adhesive layer disposed between the first circuit member and the second circuit member,
wherein the adhesive layer is composed of a cured product of the heat-curable adhesive composition according to claim 11.
